(19) United States
(12) Patent Application Publication
(10) Pub. No.: US 2024/0038824 A1
(43) Pub. Date: Feb. 1, 2024

(54) ASSEMBLY SUBSTRATE STRUCTURE OF A DISPLAY DEVICE INCLUDING A SEMICONDUCTOR LIGHT EMITTING DEVICE AND A DISPLAY DEVICE INCLUDING THE SAME

(71) Applicants: LG ELECTRONICS INC., Seoul (KR); LG DISPLAY CO., LTD., Seoul (KR)

(72) Inventors: Younho HEO, Seoul (KR); Kwangheon KIM, Seoul (KR)

(73) Assignees: LG ELECTRONICS INC., Seoul (KR); LG DISPLAY CO., LTD., Seoul (KR)

(21) Appl. No.: 18/227,653

(22) Filed: Jul. 28, 2023

(30) Foreign Application Priority Data
Jul. 29, 2022 (WO) PCT/KR2022/011244

(51) Int. Cl. H01L 27/15; G09G 3/32

(52) U.S. Cl. CPC H01L 27/156; G09G 3/32; G09G 2300/0842

(57) ABSTRACT

Discussed is an assembly substrate structure of a display device including a semiconductor light emitting device and a display device having the same. The assembly substrate structure of the display device including a semiconductor light emitting device can include an assembly substrate, a first assembly electrode and a second assembly electrode disposed spaced apart from each other on the assembly substrate, a magnetic structure disposed under the first assembly electrode and the second assembly electrode and an insulating layer disposed between the first and second assembly electrodes and the magnetic structure.

### CROSS-REFERENCE TO RELATED APPLICATION

Pursuant to 35 U.S.C. § 119(a), this application claims the benefit of an earlier filing date of and the right of priority to PCT Application No. PCT/KR2022/011244, filed on Jul. 29, 2022, the entire contents of which are hereby expressly incorporated by reference into the present application.

### BACKGROUND OF THE DISCLOSURE

### 1. Field of the Disclosure

Embodiment relates to an assembly substrate structure of a display device including a semiconductor light emitting device and a display device including the same.

### 2. Discussion of the Related Art

Large-area displays include liquid crystal displays (LCDs), OLED displays, and Micro-LED displays.

The micro-LED display is a display using micro-LED, which is a semiconductor light emitting device having a diameter or cross-sectional area of 100 μm or less, as a display device.

Micro-LED display has excellent performance in many characteristics such as contrast ratio, response speed, color reproduction rate, viewing angle, brightness, resolution, lifespan, luminous efficiency and luminance because it uses micro-LED, which is a semiconductor light emitting device, as a display device.

In particular, micro-LED displays can separate and combine screens in a modular manner, so the micro-LED display has the advantage of freely adjusting the size or resolution and the advantage of being able to implement a flexible display.

However, there is a technical problem in that it is difficult to quickly and accurately transfer the semiconductor light emitting device to the display panel because more than millions of semiconductor light emitting devices are required for a large micro-LED display.

Transfer technologies that have been recently developed include a pick and place process, a laser lift-off method, or a self-assembly method.

Among these, the self-assembly method is a method in which a semiconductor light emitting device finds an assembly position in a fluid by itself, and is an advantageous method for implement a large-screen display device.

Recently, although a micro-LED structure suitable for self-assembly has been proposed in U.S. Pat. No. 9,825,202, etc., research on a technology for manufacturing a display through self-assembly of micro-LEDs is still insufficient.

In particular, in the case of quickly transferring millions or more semiconductor light emitting devices to a large display in the related art, although the transfer speed can be improved, there is a technical problem in that the transfer error rate can be increased and the transfer yield is lowered.

In related technologies, a self-assembly type transfer process using dielectrophoresis (DEP) has been attempted, but there is a problem in that the self-assembly rate is low due to the non-uniformity of the DEP force.

On the other hand, according to undisclosed internal technology, DEP force is required for self-assembly, but due to the difficulty in uniformly controlling the DEP force, there is a problem that the semiconductor light emitting device is tilted to a place outside the normal position in the assembly hole when assembling using self-assembly.

Further, there is a problem in that the lighting rate is lowered due to the deterioration of electrical contact characteristics in the subsequent electrical contact process due to the leaning of the semiconductor light emitting device.

Therefore, according to the undisclosed internal technology, DEP force is required for self-assembly, but when using DEP force, the semiconductor light emitting device faces a technical contradiction in that the electrical contact characteristics are deteriorated due to the leaning phenomenon.

On the other hand, according to the internal technology, as the assembly substrate becomes larger and AM (Active Matrix) driving technology is applied, multi-layered organic and inorganic films are deposited, resulting in a significant increase in the weight of the assembly substrate itself. Accordingly, there is a problem in that the transfer rate is lowered due to the warpage of the large-area assembly substrate due to the increase in the weight of the assembly substrate, which causes a difference in adhesion between the assembly substrate and the magnet for assembly.

Further, according to the internal technology, if the DEP force is blocked for further processing after the LED chip is assembled in the assembly hole by the DEP force, the assembly position of the assembled LED chip is changed in the assembly hole, causing problems such as leaning to one side or being separated from the assembly hole.

### SUMMARY OF THE DISCLOSURE

One of the technical challenges of the embodiment is to solve the problem of low self-assembly rate due to non-uniformity of DEP force in the self-assembly method using dielectrophoresis (DEP).

Further, one of the technical problems of the embodiment is to solve the problem that the transfer rate is lowered due to the difference in adhesion between the assembly substrate and the magnet for assembly due to the warpage of the assembly substrate.

Further, one of the technical problems of the embodiment is to solve the problem that the assembly position of the LED chip is tilted or separated from the assembly hole when the DEP force is blocked in a subsequent process after the LED chip is assembled in the assembly hole by the DEP force.

The technical problems of the embodiment are not limited to those described in this section, and include those that can be grasped throughout the specification.

The assembly substrate structure of the display device including a semiconductor light emitting device according to the embodiment can include a substrate, a first assembly electrode and a second assembly electrode spaced apart from each other on the substrate a magnetic structure disposed under the first assembly electrode and the second assembly electrode and an insulating layer disposed between a first and second assembly electrodes and the magnetic structure.

The magnetic structure can include a magnetic through hole.

The magnetic through hole can overlap a separation space between the first assembly electrode and the second assembly electrode vertically.

The horizontal width of the magnetic structure can be less than or equal to the separation distance between the first and second assembly electrodes.

Further, the embodiment can further include an outer magnetic structure disposed around an outer periphery of the substrate.

Further, the embodiment can further include an assembly barrier wall having a predetermined assembly hole and disposed on the first and second assembly electrodes.

Further, the display device including a semiconductor light emitting device according to the embodiment can include a substrate, a first assembly electrode and a second assembly electrode disposed spaced apart from each other on the substrate, a magnetic structure disposed under the first assembly electrode and the second assembly electrode, an insulating layer disposed between the first and second assembly electrodes and the magnetic structure and a semiconductor light emitting device having a magnetic layer and disposed on the first and second assembly electrodes.

The magnetic force of the magnetic structure can be greater than that of the magnetic layer.

The thickness of the magnetic structure can be greater than that of the magnetic layer.

The magnetic structure can include a magnetic through hole.

The magnetic material through hole can be disposed in an area overlapping the semiconductor light emitting element between upper and lower portions.

The magnetic through hole can overlap a separation space between the first assembly electrode and the second assembly electrode vertically.

The horizontal width of the magnetic structure can be less than or equal to the separation distance between the first and second assembly electrodes.

A horizontal width of the magnetic structure can be less than or equal to a horizontal width of the semiconductor light emitting device.

Further, the embodiment can further include an outer magnetic structure disposed around an outer periphery of the substrate.

Further, the embodiment can further include an assembly barrier wall having a predetermined assembly hole and disposed on the first and second assembly electrodes.

The thickness of the fifth-first magnetic structure disposed on the outer portion of the substrate can be greater than the thickness of the fifth-second magnetic structure disposed on the center portion of the assembly substrate.

According to the assembly substrate structure of the display device including a semiconductor light emitting device according to the embodiment and the display device including the same, in the self-assembly method using dielectrophoresis (DEP), there is a technical effect that can solve the problem of low self-assembly rate due to non-uniformity of DEP force.

Further, according to the embodiment, it is possible to solve the problem that the transfer rate is lowered due to the difference in adhesion between the assembly substrate and the assembly magnet due to the warpage of the assembly substrate.

For example, according to the embodiment, as the distance between the center portion and the edge portion of the substrate is uniformly controlled by the first magnetic force MF1 generated between the magnetic structure disposed on a substrate and the assembly device and a permanent magnet or an electromagnet, warpage of the assembly substrate can be prevented. Accordingly, there is a special technical effect of improving the transfer rate by uniformly controlling the adhesion between the assembly substrate and the assembly magnet.

Further, according to the embodiment, if the DEP force is blocked in the subsequent process after the LED chip is assembled in the assembly hole by the DEP force, it can solve the problem that the LED chip is tilted or separated from the assembly position in the assembly hole.

For example, according to the embodiment, in a situation in which the DEP force is removed after the semiconductor light emitting device is assembled in the assembly hole using the DEP force, as the semiconductor light emitting device can be fixed in the assembly position by the third magnetic force MF3, which is an attractive force generated between the magnetic structure disposed on the substrate and the magnetic layer of the semiconductor light emitting device, there is a special technical effect that a highly reliable wiring process can be performed without using a separate fixing material in the subsequent wiring process.

Also in the second embodiment, as the second magnetic structure includes a magnetic through hole, and the second magnetic force MF2 of the assembly device is more effectively applied to the semiconductor light emitting device through the magnetic through hole, there is a special technical effect that can further improve assembly efficiency.

Further, the third embodiment has a technical effect of maintaining the assembly position of the semiconductor light emitting device at the center of the assembly hole as the third magnetic structure is disposed in an area overlapping the semiconductor light emitting device vertically.

Further, according to the fourth embodiment, as the fourth magnetic structure is disposed on the outer periphery of the assembly substrate, the distance between the substrate center and the edge portion of the substrate is more uniformly controlled by the magnetic force generated between the fourth magnetic structure and the assembling device, which is a permanent magnet or an electromagnet, to prevent warpage, thereby improving the transfer rate.

Further, according to the fifth embodiment, as the thickness of the fifth-first magnetic structure disposed on the outer portion of the assembly substrate is increased, there is a technical effect of improving the transfer rate by preventing warpage of the substrate, which is likely to occur at the edge portion of the substrate due to the greater magnetic force generated with the assembly device.

The technical effects of the embodiments are not limited to those described in this section, and include those understood from the description of the invention.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is an exemplary view of a living room of a house in which a display device according to an embodiment is disposed.

FIG. 2 is a schematic block diagram of a display device according to an embodiment.

FIG. 3 is a circuit diagram showing an example of a pixel of FIG. 2.

FIG. 4 is an enlarged view of a first panel area in the display device of FIG. 1.

FIG. 5 is a cross-sectional view taken along line B1-B2 in area A2 of FIG. 4.

FIG. 6 is an exemplary view in which a light emitting device according to an embodiment is assembled to a substrate by a self-assembly method.

FIG. 7 is a partially enlarged view of area A3 of FIG. 6.

FIGS. 8A and 8B are examples of self-assembly in the display device according to the internal technology.

FIG. 8C is a picture of self-assembly in the display device according to the internal technology.

FIG. 8D is a diagram showing a tilt phenomenon that occurs during self-assembly of an internal technology.

FIG. 8E is a diagram illustrating warpage of an assembly substrate that can occur during self-assembly according to internal technology.

FIG. 9 is a cross-sectional view of a display device including a semiconductor light emitting device according to the first embodiment.

FIG. 10 is an exemplary view of a assembly electrode structure of a display device including a semiconductor light emitting device according to the first embodiment.

FIGS. 11A to 11E are views illustrating assembly features of the display device 301 including the semiconductor light emitting device according to the first embodiment.

FIG. 12A is a cross-sectional view of a display device including a semiconductor light emitting device according to a second embodiment.

FIG. 12B is an exemplary view illustrating assembly characteristics of a display device 302 including a semiconductor light emitting device according to the second embodiment.

FIG. 13 is a cross-sectional view of a display device including a semiconductor light emitting device according to a third embodiment.

FIG. 14 is a plan view of an assembly substrate and a fourth magnetic structure in a display device including a semiconductor light emitting device according to a fourth embodiment.

FIG. 15 is a cross-sectional view of an assembly substrate and a fifth magnetic structure in a display device including a semiconductor light emitting device according to a fifth embodiment.

### DETAILED DESCRIPTION OF THE EMBODIMENTS

Hereinafter, embodiments disclosed in the present description will be described in detail with reference to the accompanying drawings. The suffixes ‘module’ and ‘part’ for components used in the following description are given or mixed in consideration of ease of specification, and do not have a meaning or role distinct from each other by themselves. Further, the accompanying drawings are provided for easy understanding of the embodiments disclosed in the present specification, and the technical ideas disclosed in the present specification are not limited by the accompanying drawings. Further, when an element, such as a layer, area, or substrate, is referred to as being ‘on’ another component, this includes that it is directly on the other element or there can be other intermediate elements in between.

The display device described in this specification includes a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in this specification can be applied to a device capable of displaying even a new product type to be developed in the future.

Hereinafter, a light emitting device and a display device including the light emitting device according to the embodiment will be described.

Hereinafter, an assembly substrate structure of a display device including a semiconductor light emitting device according to an embodiment and a display device including the same will be described.

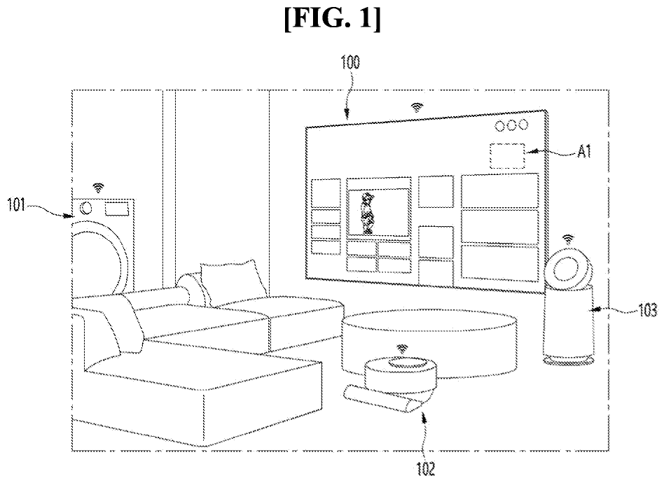

FIG. 1 shows a living room of a house in which a display device 100 according to an embodiment is disposed.

The display device 100 of the embodiment can display the status of various electronic products such as the washing machine 101, the robot cleaner 102, and the air purifier 103, and communicate with each electronic product based on IOT, and can control each electronic product based on the user's setting data.

The display apparatus 100 according to the embodiment can include a flexible display manufactured on a thin and flexible substrate. The flexible display can be bent or rolled like paper while maintaining the characteristics of a conventional flat panel display.

In the flexible display, visual information can be implemented by independently controlling light emission of unit pixels arranged in a matrix form. A unit pixel means a minimum unit for realizing one color. The unit pixel of the flexible display can be implemented by a light emitting device. In an embodiment, the light emitting device can be a Micro-LED or a Nano-LED, but is not limited thereto.

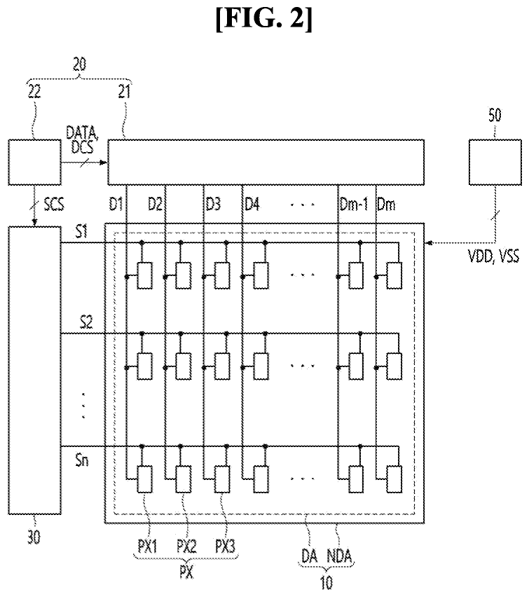

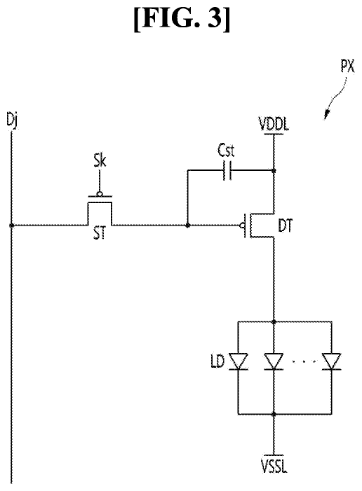

Next, FIG. 2 is a block diagram schematically showing a display device according to an embodiment, and FIG. 3 is a circuit diagram showing an example of the pixel of FIG. 2.

Referring to FIGS. 2 and 3, the display device according to the embodiment can include a display panel 10, a driving circuit 20, a scan driving unit 30, and a power supply circuit 50.

The display device 100 according to the embodiment can drive the light emitting device using an active matrix (AM) method or a passive matrix (PM, passive matrix) method.

The driving circuit 20 can include a data driving unit 21 and a timing control unit 22.

The display panel 10 can be divided into a display area DA and a non-display area NDA disposed around the display area DA. The display area DA is an area in which pixels PX are formed to display an image. The display panel 10 includes data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn can be included.

Each of the pixels PX can include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 emits a third color light of a wavelength can be emitted. The first color light can be red light, the second color light can be green light, and the third color light can be blue light, but is not limited thereto. Further, although it is illustrated that each of the pixels PX includes three sub-pixels in FIG. 2, the present invention is not limited thereto. For example, each of the pixels PX can include four or more sub-pixels.

Each of the first sub-pixel PX1, the second sub-pixel PX2, and the third sub-pixel PX3 can connected to at least one of the data lines D1 to Dm, and at least one of the scan lines S1 to Sn, and a high potential voltage line. As shown in FIG. 3, the first sub-pixel PX1 can include the light emitting devices LD, plurality of transistors for supplying current to the light emitting devices LD, and at least one capacitor Cst.

Each of the first sub-pixel PX1, the second sub-pixel PX2, and the third sub-pixel PX3 can include only one light emitting device LD and at least one capacitor Cst.

Each of the light emitting devices LD can be a semiconductor light emitting diode including a first electrode, a plurality of conductivity type semiconductor layers, and a second electrode. Here, the first electrode can be an anode electrode and the second electrode can be a cathode electrode, but the present invention is not limited thereto.

Referring to FIG. 3, the plurality of transistors can include a driving transistor DT for supplying current to the light emitting devices LD, and a scan transistor ST for supplying a data voltage to the gate electrode of the driving transistor DT. The driving transistor DT can include a gate electrode connected to the source electrode of the scan transistor ST, a source electrode connected to a high potential voltage line to which a high potential voltage is applied, and a drain electrode connected to first electrodes of the light emitting devices LD. The scan transistor ST can include a gate electrode connected to the scan line Sk, where k is an integer satisfying 1≤k≤n, a source electrode connected to the gate electrode of the driving transistor DT, and a drain electrode connected to data lines Dj, where j is integer satisfying 1≤j≤m.

The capacitor Cst is formed between the gate electrode and the source electrode of the driving transistor DT. The storage capacitor Cst can charge a difference between the gate voltage and the source voltage of the driving transistor DT.

The driving transistor DT and the scan transistor ST can be formed of a thin film transistor. Further, although the driving transistor DT and the scan transistor ST have been mainly described in FIG. 3 as being formed of a P-type MOSFET (Metal Oxide Semiconductor Field Effect Transistor), the present invention is not limited thereto. The driving transistor DT and the scan transistor ST can be formed of an N-type MOSFET. In this case, the positions of the source electrode and the drain electrode of each of the driving transistor DT and the scan transistor ST can be changed.

Further, in FIG. 3 has been illustrated each of the first sub-pixel PX1, the second sub-pixel PX2, and the third sub-pixel PX3 includes one driving transistor DT, one scan transistor ST, and 2T1C (2 Transistor-1 capacitor) having a capacitor Cst, but the present invention is not limited thereto. Each of the first sub-pixel PX1, the second sub-pixel PX2, and the third sub-pixel PX3 can include a plurality of scan transistors ST and a plurality of capacitors Cst.

Referring back to FIG. 2, the driving circuit 20 outputs signals and voltages for driving the display panel 10. To this end, the driving circuit 20 can include a data driver 21 and a timing controller 22.

The data driver 21 receives digital video data DATA and a source control signal DCS from the timing controller 22. The data driver 21 converts the digital video data DATA into analog data voltages according to the source control signal DCS and supplies them to the data lines D1 to Dm of the display panel 10.

The timing controller 22 receives digital video data DATA and timing signals from the host system. The timing signals can include a vertical sync signal, a horizontal sync signal, a data enable signal, and a dot clock. The host system can be an application processor of a smartphone or tablet PC, a monitor, or a system-on-chip of a TV.

The scan driver 30 receives the scan control signal SCS from the timing controller 22. The scan driver 30 generates scan signals according to the scan control signal SCS and supplies them to the scan lines S1 to Sn of the display panel 10. The scan driver 30 can include a plurality of transistors and can be formed in the non-display area NDA of the display panel 10. Further, the scan driver 30 can be formed of an integrated circuit, and in this case, can be mounted on a gate flexible film attached to the other side of the display panel 10.

The power supply circuit 50 generates a high potential voltage VDD and a low potential voltage VSS for driving the light emitting devices LD of the display panel 10 from the main power source, and the power supply circuit can supply VDD and VSS to the high-potential voltage line and the low-potential voltage line of the display panel 10. Further, the power supply circuit 50 can generate and supply driving voltages for driving the driving circuit 20 and the scan driving unit 30 from the main power.

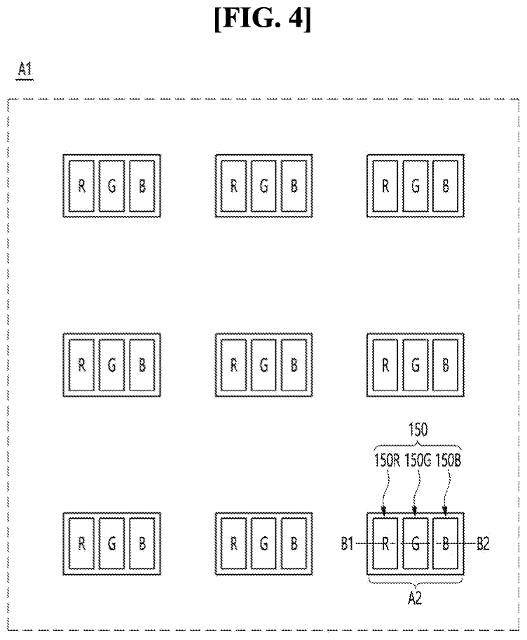

Next, FIG. 4 is an enlarged view of the first panel area A1 in the display device of FIG. 1.

Referring to FIG. 4, the display device 100 according to the embodiment can be manufactured by mechanically and electrically connecting a plurality of panel areas such as the first panel area A1 by tiling.

The first panel area A1 can include a plurality of light emitting devices 150 arranged for each unit pixel (PX in FIG. 2).

For example, the unit pixel PX can include a first sub-pixel PX1, a second sub-pixel PX2, and a third sub-pixel PX3. For example, a plurality of red light-emitting devices 150R are disposed in the first sub-pixel PX1, a plurality of green light-emitting devices 150G are disposed in the second sub-pixel PX2, and a plurality of blue light-emitting devices 150B are disposed in the third sub-pixel PX3. The unit pixel PX can further include a fourth sub-pixel in which a light emitting device is not disposed, but is not limited thereto. Meanwhile, the light emitting device 150 can be the semiconductor light emitting device.

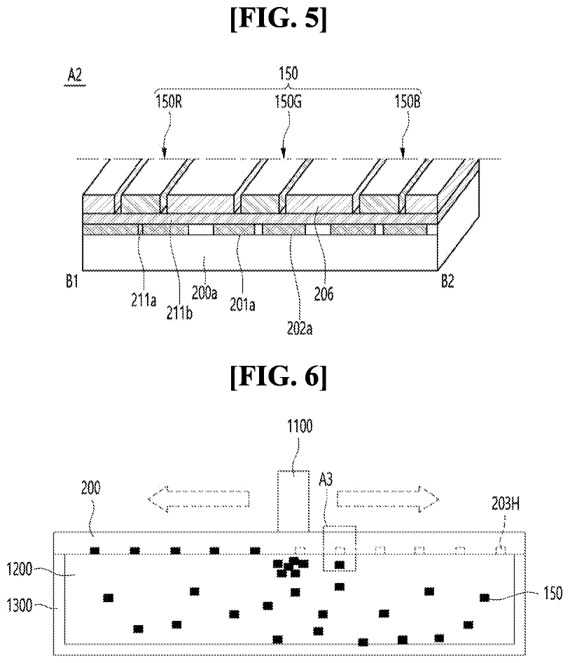

Next, FIG. 5 is a cross-sectional view taken along line B1-B2 of area A2 of FIG. 4.

Referring to FIG. 5, the display device 100 of the embodiment includes a substrate 200a, wirings 201a and 202a spaced apart from each other, a first insulating layer 211a, a second insulating layer 211b, a third insulating layer 206 and a plurality of light emitting devices 150.

The wiring can include a first wiring 201a and a second wiring 202a spaced apart from each other. The first wiring 201a and the second wiring 202a can function as panel wiring for applying power to the light emitting device 150 in the panel, and in the case of self-assembly of the light emitting device 150, further, the first wiring 201a and the second wiring 202a can function as an assembly electrode for generating a dielectrophoresis force.

The wirings 201a and 202a can be formed of a transparent electrode (ITO) or include a metal material having excellent electrical conductivity. For example, the wirings 201a and 202a can be formed at least one of titanium (Ti), chromium (Cr), nickel (Ni), aluminum (A1), platinum (Pt), gold (Au), tungsten (W), molybdenum (Mo) or an alloy thereof.

A first insulating layer 211a can be disposed between the first wiring 201a and the second wiring 202a, and a second insulating layer 211b can be disposed on the first wiring 201a and the second wiring 202a. The first insulating layer 211a and the second insulating layer 211b can be an oxide film, a nitride film, or the like, but are not limited thereto.

The light emitting device 150 can include a red light emitting device 150R, a green light emitting device 150G, and a blue light emitting device 150B0 to form a sub-pixel, respectively, but is not limited thereto. The light emitting device 150 can include a red phosphor and a green phosphor to implement red and green, respectively.

The substrate 200a can be formed of glass or polyimide. Further, the substrate 200a can include a flexible material such as polyethylene naphthalate (PEN) or polyethylene terephthalate (PET). Further, the substrate 200 can include a transparent material, but is not limited thereto. The substrate 200a can function as a support substrate in the panel, and can function as a substrate for assembly when self-assembling the light emitting device.

The third insulating layer 206 can include an insulating and flexible material such as polyimide, PEN, or PET, and can be integrally formed with the substrate 200a to form one substrate.

The third insulating layer 206 can be a conductive adhesive layer having adhesiveness and conductivity, and the conductive adhesive layer can be flexible to enable a flexible function of the display device. For example, the third insulating layer 206 can be an anisotropy conductive film (ACF) or a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

The distance between the first and second wirings 201a and 202a is formed to be smaller than the width of the light emitting device 150 and the width of the assembly hole 203H, so that the assembly position of the light emitting device 150 using an electric field can be more precisely fixed.

A third insulating layer 206 is formed on the first and second wirings 201a and 202a to protect the first and second wirings 201a and 202a from the fluid 1200, and the third insulating layer 206 can prevent leakage of current flowing through the two wirings 201a and 202a. The third insulating layer 206 can be formed of a single layer or multiple layers of an inorganic insulator such as silica or alumina or an organic insulator.

Further, the third insulating layer 206 can include an insulating and flexible material such as polyimide, PEN, PET, etc., and can be formed integrally with the substrate 200 to form a single substrate.

The third insulating layer 206 has a barrier wall, and an assembly hole 203H can be formed by the barrier wall. For example, the third insulating layer 206 can include an assembly hole 203H through which the light emitting device 150 is inserted (refer to FIG. 6). Accordingly, during self-assembly, the light emitting device 150 can be easily inserted into the assembly hole 203H of the third insulating layer 206. The assembly hole 203H can be referred to as an insertion hole, a fixing hole, or an alignment hole.

The assembly hole 203H can have a shape and a size corresponding to the shape of the light emitting device 150 to be assembled at a corresponding position. Accordingly, it is possible to prevent other light emitting devices from being assembled in the assembly hole 203H or from assembling a plurality of light emitting devices.

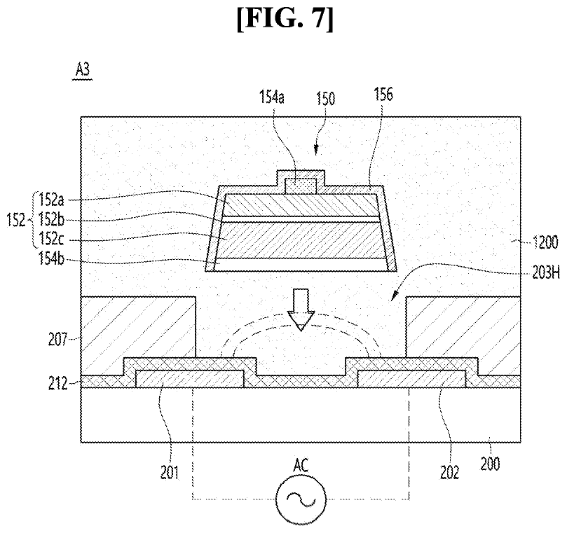

Next, FIG. 6 is a view showing an example in which a light emitting device according to an embodiment is assembled to a substrate by a self-assembly method, and FIG. 7 is a partially enlarged view of an area A3 of FIG. 6, and FIG. 7 is a view in which area A3 is rotated 180 degrees for convenience of description.

An example of assembling the semiconductor light emitting device according to the embodiment to a display panel by a self-assembly method using an electromagnetic field will be described based on FIGS. 6 and 7.

The substrate (or the assembly substrate) 200 described below can also function as a panel substrate 200a in a display device after assembling a light emitting device, but the embodiment is not limited thereto.

Referring to FIG. 6, the semiconductor light emitting device 150 can be put into the chamber 1300 filled with the fluid 1200, and the semiconductor light emitting device 150 by the magnetic field generated from the assembly device 1100 can move to the assembly substrate 200. In this case, the light emitting device 150 adjacent to the assembly hole 203H of the assembly substrate 200 can be assembled in the assembly hole 203H by a dielectrophoretic force by an electric field of the assembly electrodes. The fluid 1200 can be water such as ultrapure water, but is not limited thereto. A chamber can be referred to as a water bath, container, vessel, or the like.

After the semiconductor light emitting device 150 is put into the chamber 1300, the assembly substrate 200 can be disposed on the chamber 1300. According to an embodiment, the assembly substrate 200 can be introduced into the chamber 1300.

Referring to FIG. 7, the semiconductor light emitting device 150 can be implemented as a vertical semiconductor light emitting device as shown, but is not limited thereto, and a horizontal light emitting device can be employed.

The semiconductor light emitting device 150 can include a magnetic layer having a magnetic material. The magnetic layer can include a magnetic metal such as nickel (Ni). Since the semiconductor light emitting device 150 injected into the fluid includes a magnetic layer, it can move to the assembly substrate 200 by the magnetic field generated from the assembly device 1100. The magnetic layer can be disposed above or below or on both sides of the light emitting device.

The semiconductor light emitting device 150 can include a passivation layer 156 surrounding the top and side surfaces. The passivation layer 156 can be formed by using an inorganic insulator such as silica or alumina through PECVD, LPCVD, sputtering deposition, or the like. Further, the passivation layer 156 can be formed through a method of spin coating an organic material such as a photoresist or a polymer material.

The semiconductor light emitting device 150 can include a first conductivity type semiconductor layer 152a, a second conductivity type semiconductor layer 152c, and an active layer 152b disposed between the first conductivity type semiconductor layer 152a and the second conductivity type semiconductor layer 152c. The first conductivity type semiconductor layer 152a can be an n-type semiconductor layer, and the second conductivity type semiconductor layer 152c can be a p-type semiconductor layer, but is not limited thereto.

A first electrode layer 154a can be disposed on the first conductivity type semiconductor layer 152a, and a second electrode layer 154b can be disposed on the second conductivity type semiconductor layer 152c. To this end, a partial area of the first conductivity type semiconductor layer 152a or the second conductivity type semiconductor layer 152c can be exposed to the outside. Accordingly, after the semiconductor light emitting device 150 is assembled on the assembly substrate 200, a portion of the passivation layer 156 can be etched in the manufacturing process of the display device.

The assembly substrate 200 can include a pair of first assembly electrodes 201 and second assembly electrodes 202 corresponding to each of the semiconductor light emitting devices 150 to be assembled. The first assembly electrode 201 and the second assembly electrode 202 can be formed by stacking a single metal, a metal alloy, or a metal oxide in multiple layers. For example, the first assembly electrode 201 and the second assembly electrode 202 can be formed including at least one of Cu, Ag, Ni, Cr, Ti, Al, Rh, Pd, Ir, Ru, Mg, Zn, Pt, Au, or Hf, but is not limited thereto.

Further, the first assembly electrode 201 and the second assembly electrode 202 can be formed including at least one of indium tin oxide (ITO), indium zinc oxide (IZO), indium zinc tin oxide (IZTO), indium aluminum zinc oxide (IAZO), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, or Ni/IrOx/Au/ITO, but it is not limited thereto.

The first assembly electrode 201, the second assembly electrode 202 emits an electric field as an AC voltage is applied, the semiconductor light emitting device 150 inserted into the assembly hole 203H can be fixed by dielectrophoretic force. A distance between the first assembly electrode 201 and the second assembly electrode 202 can be smaller than a width of the semiconductor light emitting device 150 and a width of the assembly hole 203H, the assembly position of the semiconductor light emitting device 150 using the electric field can be more precisely fixed.

An insulating layer 212 is formed on the first assembly electrode 201 and the second assembly electrode 202 to protect the first assembly electrode 201 and the second assembly electrode 202 from the fluid 1200 and leakage of current flowing through the first assembly electrode 201 and the second assembly electrode 202 can be prevented. For example, the insulating layer 212 can be formed of a single layer or multiple layers of an inorganic insulator such as silica or alumina or an organic insulator. The insulating layer 212 can have a minimum thickness to prevent damage to the first assembly electrode 201 and the second assembly electrode 202 when the semiconductor light emitting device 150 is assembled, and it can have a maximum thickness for the semiconductor light emitting device 150 being stably assembled.

A barrier wall 207 can be formed on the insulating layer 212. A portion of the barrier wall 207 can be positioned on the first assembly electrode 201 and the second assembly electrode 202, and the remaining area can be positioned on the assembly substrate 200.

On the other hand, when the assembly substrate 200 is manufactured, a portion of the barrier walls formed on the entire upper portion of the insulating layer 212 is removed, an assembly hole 203H in which each of the semiconductor light emitting devices 150 is coupled and assembled to the assembly substrate 200 can be formed.

An assembly hole 203H to which the semiconductor light emitting devices 150 are coupled is formed in the assembly substrate 200, and a surface on which the assembly hole 203H is formed can be in contact with the fluid 1200. The assembly hole 203H can guide an accurate assembly position of the semiconductor light emitting device 150.

Meanwhile, the assembly hole 203H can have a shape and size corresponding to the shape of the semiconductor light emitting device 150 to be assembled at the corresponding position. Accordingly, it is possible to prevent assembly of other semiconductor light emitting devices or a plurality of semiconductor light emitting devices into the assembly hole 203H.

Referring back to FIG. 6, after the assembly substrate 200 is disposed in the chamber, the assembly device 1100 for applying a magnetic field can move along the assembly substrate 200. The assembly device 1100 can be a permanent magnet or an electromagnet.

The assembly device 1100 can move while in contact with the assembly substrate 200 in order to maximize the area applied by the magnetic field into the fluid 1200. According to an embodiment, the assembly device 1100 can include a plurality of magnetic materials or a magnetic material having a size corresponding to that of the assembly substrate 200. In this case, the moving distance of the assembly device 1100 can be limited within a predetermined range.

The semiconductor light emitting device 150 in the chamber 1300 can move toward the assembly device 1100 and the assembly substrate 200 by the magnetic field generated by the assembly device 1100.

Referring to FIG. 7, while moving toward the assembly device 1100, the semiconductor light emitting device 150 can enter into the assembly hole 203H and be fixed by a dielectrophoretic force (DEP force) generated by an electric field of an assembly electrode of an assembly substrate.

Specifically, the first and second assembly wirings 201 and 202 can form an electric field by an AC power source, and a dielectrophoretic force can be formed between the assembly wirings 201 and 202 by this electric field. The semiconductor light emitting device 150 can be fixed to the assembly hole 203H on the assembly substrate 200 by this dielectrophoretic force.

At this time, a predetermined solder layer is formed between the light emitting device 150 and the assembly electrode assembled on the assembly hole 203H of the assembly substrate 200 to can improve the bonding force of the light emitting device 150.

Further, a molding layer can be formed in the assembly hole 203H of the assembly substrate 200 after assembly. The molding layer can be a transparent resin or a resin including a reflective material and a scattering material.

By the self-assembly method using the electromagnetic field described above, the time required for each of the semiconductor light emitting devices to be assembled on the substrate can be rapidly reduced, so that a large-area high-pixel display can be implemented more quickly and economically.

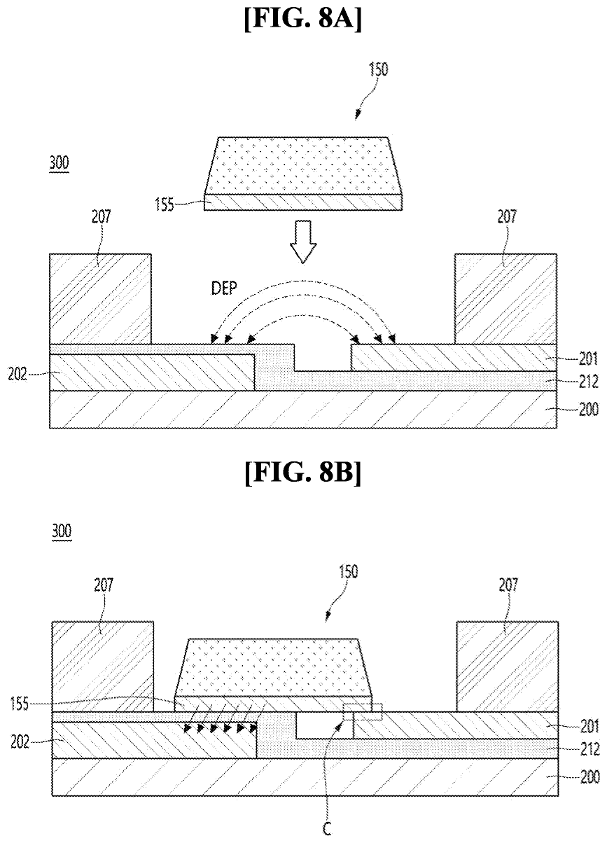

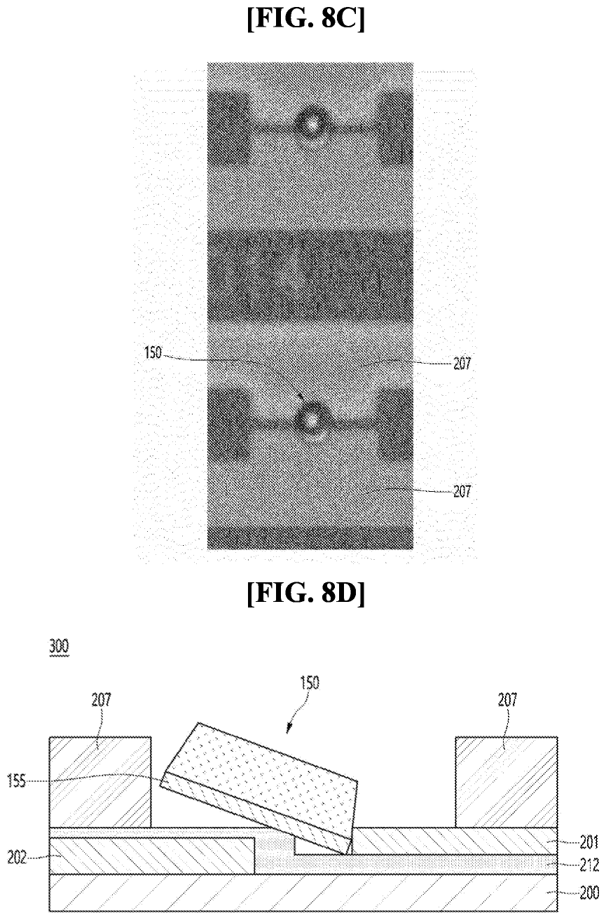

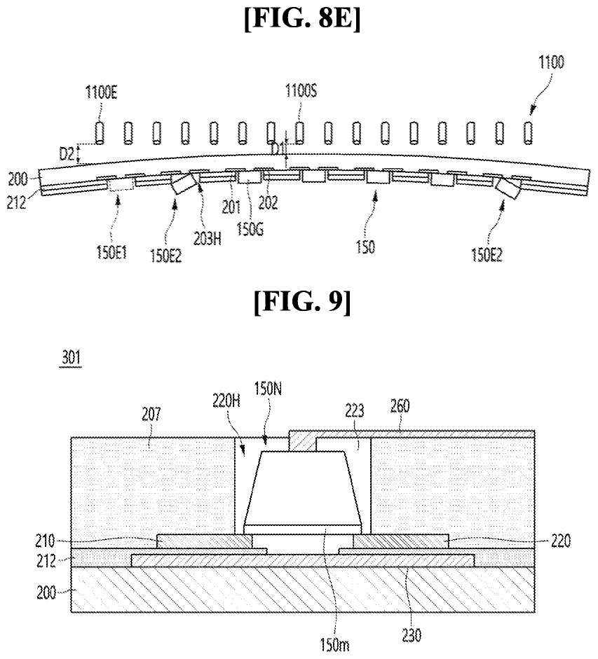

Next, FIGS. 8A and 8B are self-assembling examples of the display device 300 according to the internal technology, and FIG. 8C is a self-assembly picture of the display device according to the internal technology.

In the display device 300 according to the internal technology, either the first assembly electrode 201 or the second assembly electrode 202 is brought into contact with the bonding metal 155 of the semiconductor light emitting device 150 through a bonding process.

However, in order to solve the problem that the bonding area is also reduced as the semiconductor light emitting device 150 is miniaturized, as shown in FIGS. 8A to 8B, a method of omitting the existing Vdd line and completely opening its role to one side of the electrode wiring is used.

However, when this method is used, the semiconductor light emitting device 150 drawn to the first assembly electrode 201 by DEP in the fluid comes into contact with the first assembly electrode 201 and becomes conductive. Accordingly, the electric field force is concentrated on the second assembly electrode 202 that is not opened by the insulating layer 212, and as a result, there is a problem in that the assembly is biased in one direction.

Referring to FIGS. 8B and 8C, the contact area C between the bonding metal 155 of the semiconductor light emitting device 150 and the first assembly electrode 201 functioning as a panel electrode is very small, so poor contact can be occurred.

For example, according to the undisclosed internal technology, DEP Force is required for self-assembly, due to the difficulty of uniform control of the DEP force, there is a problem in that the semiconductor light emitting device tilts to a different place in the assembly hole during assembly using self-assembly.

Further, due to this tilt phenomenon of the semiconductor light emitting device, electrical contact characteristics are lowered in the subsequent electrical contact process, resulting in a defective lighting rate and a lower yield.

Therefore, according to the unpublished internal technology, DEP Force is required for self-assembly, but when using the DEP Force, the semiconductor light emitting device faces a technical contradiction in which electrical contact characteristics are reduced due to the tilt phenomenon.

Next, FIG. 8D is a diagram illustrating a tilt phenomenon that can occur during self-assembly according to an internal technology.

According to the internal technology, the insulating layer 212 is disposed on the first and second assembly electrodes 201 and 202 on the assembly substrate 200, assembly Self-assembly of the semiconductor light emitting device 150 by dielectrophoretic force was performed in the assembly hole 220H set by the assembly barrier wall 207. However, according to internal technology, the electric field force is concentrated on the second assembly electrode 202, and as a result, there is a problem that the assembly is biased in one direction, and as a result, the self-assembly is not properly performed and the problem of tilting in the assembly hole 220H has been studied.

Next, FIG. 8E is a view illustrating warpage of the assembly substrate 200 that can occur during self-assembly according to internal technology.

An example of assembling a semiconductor light emitting device according to an internal technology to a display panel by a self-assembly method using a magnetic field and an electromagnetic field will be described.

Referring to FIG. 8E, the semiconductor light emitting device 150 can be put into a chamber filled with fluid, and the semiconductor light emitting device 150 can move to the assembly substrate 200 by a magnetic field generated from the assembly device 1100 such as a magnet. At this time, the light emitting device 150 adjacent to the assembly hole 203H of the assembly substrate 200 can be assembled into the assembly hole by dielectrophoretic (DEP) force generated by the electric field of the assembly electrodes.

However, according to the internal technology, as the assembly substrate 200 is enlarged and AM (Active Matrix) driving technology is applied, multi-layered organic and inorganic films are deposited, resulting in a significant increase in the weight of the assembly substrate itself. As a result, warpage of the large-area assembly substrate occurs, resulting in a difference in adhesion between the assembly substrate 200 and the assembly apparatus 1100, which is a magnet for assembly, resulting in a low transfer rate.

Specifically, when the large area assembly substrate 200 is warped and the distance between the assembly substrate 200 in the center portion and the first assembly device 1100S located above the assembly substrate 200 is the first distance D1, the distance between the edge portion of the assembly substrate 200 and the second assembly device 1100E positioned above the assembly substrate 200 is a second distance D2 greater than the first distance D1. As described above, according to the internal technology, there is a problem in that the transfer rate is lowered due to a difference in adhesion between the large area assembly substrate 200 and the assembly device 1100, which is a magnet for assembly.

For example, the first semiconductor light emitting device 150G can be properly assembled in the assembly hole 220H of the center portion of the assembly substrate 200.

However, in the edge area of the assembly substrate 200 where the adhesion is poor, the second semiconductor light emitting device 150E2 assembled in a tilted state can occur in the assembly hole 220H, and even the unassembled third semiconductor light emitting device 150E1 can occur in the assembly hole 220H.

As described above, according to the internal technology, there is a problem in that the transfer rate is lowered due to a difference in adhesion between the large area assembly substrate 200 and the assembly device 1100, which is a magnet for assembly.

Further, according to the internal technology, when the DEP force is blocked in the subsequent process after the LED chip is assembled in the assembly hole by electric force using magnetic force and DEP force, there is a problem that the assembled LED chip is shifted from the assembly hole to the assembly position or is further separated from the assembly hole.

Accordingly, one of the technical challenges of the embodiment is to solve the problem of low self-assembly rate due to non-uniformity of DEP force in the self-assembly method using dielectrophoresis (DEP).

Further, one of the technical problems of the embodiment is to solve the problem that the transfer rate is lowered due to the difference in adhesion between the assembly substrate and the assembly magnet due to the warpage of the assembly substrate.

Further, one of the technical challenges of the embodiment is to solve the problem that the assembled LED chip is displaced from the assembly hole or further away from the assembly hole when the DEP force is blocked in the subsequent process after the LED chip is assembled in the assembly hole by electric force using magnetic force and DEP force.

Hereinafter, a display device 301 including a semiconductor light emitting device according to an embodiment capable of solving the technical problem will be described with reference to the following drawings.

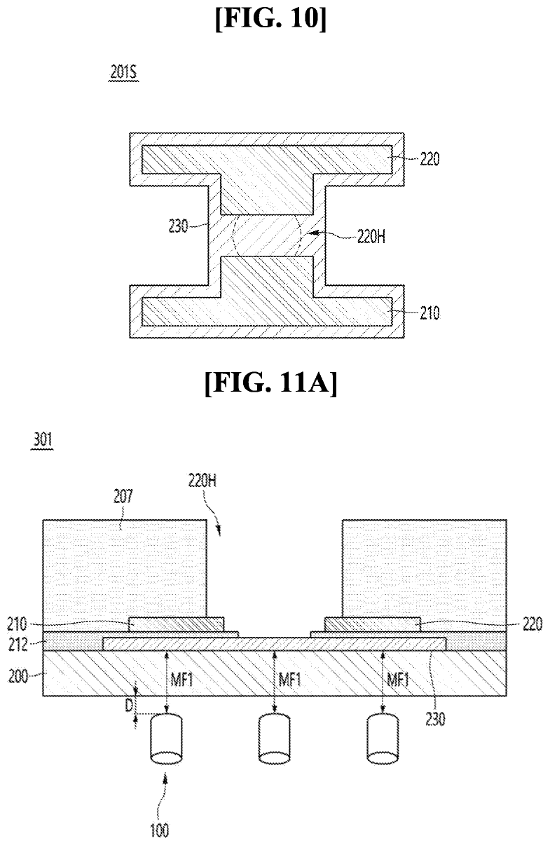

FIG. 9 is a cross-sectional view of the display device 301 including the semiconductor light emitting device according to the first embodiment. FIG. 10 is an exemplary view of a assembly electrode structure 201S of a display device 301 including a semiconductor light emitting device according to the first embodiment. (Hereinafter, ‘first embodiment’ will be abbreviated as ‘embodiment’)

Referring to FIG. 9, a display device 301 including a semiconductor light emitting device according to an embodiment can include a substrate 200, a first assembly electrode 210 and a second assembly electrode 220 disposed on the substrate 200, a magnetic structure (or a first magnetic structure) 230 disposed under the first assembly electrode 210 and the second assembly electrode 220, an insulating layer 212 disposed between the first and second assembly electrodes 210 and 220 and the magnetic structure 230, an assembly barrier wall 207 including a predetermined assembly hole 220H and disposed on the first and second assembly electrodes 210 and 220, and a semiconductor light emitting device 150N disposed in the assembly hole 220H.

The semiconductor light emitting device 150N can include a predetermined magnetic layer 150M.

The magnetic force of the magnetic structure 230 can be greater than that of the magnetic layer 150M.

For example, the magnetic structure 230 can include a neodymium magnet, and the magnetic layer 150M of the semiconductor light emitting device can include any one of nickel, cobalt, or iron.

The magnetic structure 230 can have a thickness greater than that of the magnetic layer 150M, but is not limited thereto. The magnetic structure 230 can have a thickness of about 50 nm to about 2 μm, but is not limited thereto.

Further, the embodiment can include a predetermined light-transmitting resin 223 filled in the assembly hole 220H and a second panel wiring 260 electrically connected to the semiconductor light emitting device 150N.

Referring to FIGS. 9 and 10, an assembly electrode structure 201S according to an embodiment can include first and second assembly electrodes 210 and 220 spaced apart from each other and a magnetic structure 230 disposed under the first and second assembly electrodes 210 and 220.

The magnetic structure 230 can have an open structure not covered by the insulating layer 212 in the area of the assembly hole 220H, but is not limited thereto.

According to the embodiment, there is a technical effect that can solve the problem that the transfer rate is lowered due to the difference in adhesion between the assembly substrate and the magnet for assembly due to the warpage of the assembly substrate.

Further, according to the embodiment, after the LED chip is assembled in the assembly hole by electric force using magnetic force and DEP Force, in the subsequent process, when the DEP force is blocked, it is possible to solve the problem that the assembled LED chip is shifted from the assembly hole or moved away from the assembly hole.

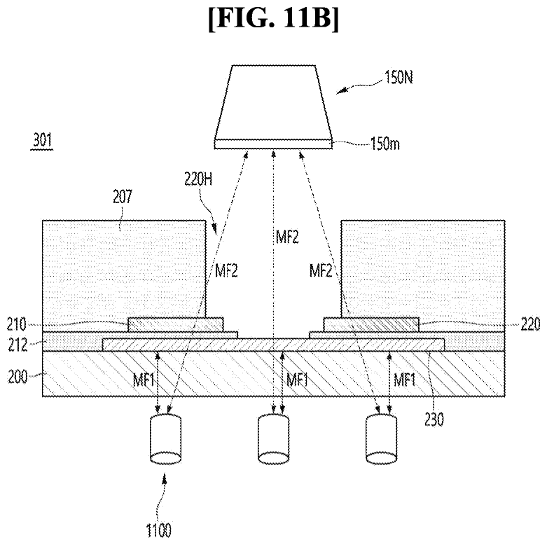

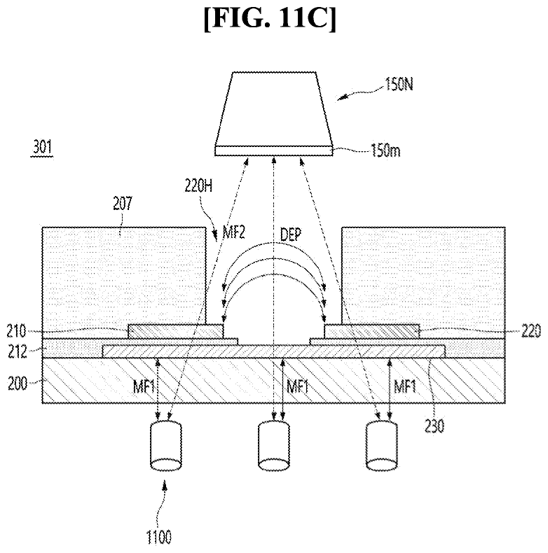

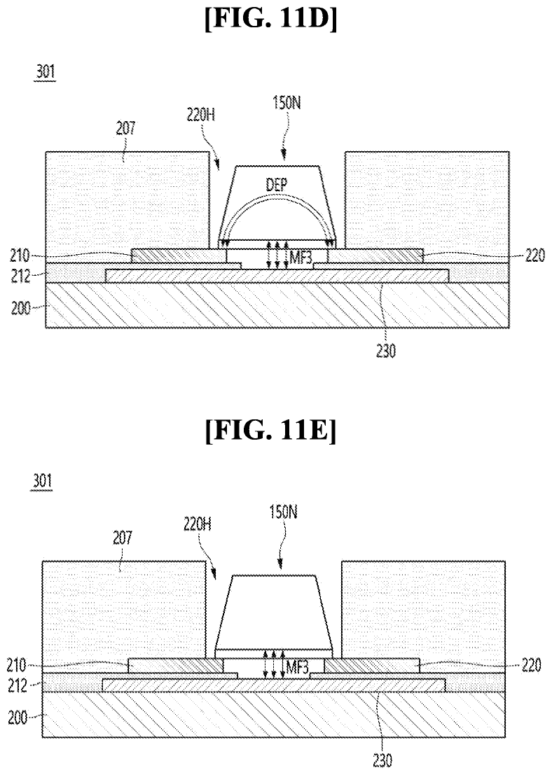

Hereinafter, technical characteristics of a display device 301 including an assembly electrode structure 201S of a display device including a semiconductor light emitting device according to an embodiment will be described with reference to FIGS. 11A to 11E.

Referring to FIG. 11A, an assembly substrate 200 including a first assembly electrode structure 201S is disposed in a fluid, and the warpage of the assembly substrate 200 can be prevented by the first magnetic force generated from the assembly device 1100 such as a magnet.

As described above, according to the internal technology, there is a problem in that the transfer rate is lowered due to a difference in adhesion between the assembly substrate 200 and the assembly device 1100, which is a magnet for assembly, due to warpage of the large area assembly substrate.

However, according to the embodiment, by the first magnetic force MF1 generated between the magnetic structure 230 disposed on the assembly substrate 200 and the assembly device 1100, which is a permanent magnet or an electromagnet, a distance D between the center portion and the edge portion of the assembly substrate 200 can be uniformly controlled, and warpage of the assembly substrate 200 can be prevented. Accordingly, there is a special technical effect of improving the transfer rate by uniformly controlling the adhesion between the assembly substrate and the magnet for assembly.

Next, referring to FIG. 11B, the semiconductor light emitting device 150N having the magnetic layer 150M injected into the fluid can be guided to the assembly hole 220H area of the assembly substrate 200 by the second magnetic force MF2 of the assembly device 1100. At this time, a first magnetic force MF1 is generated between the assembly device 1100 and the magnetic structure 230 disposed on the assembly substrate 200, and assembly proceeds while the warpage of the assembly substrate 200 is prevented, so the transfer rate can be improved.

At this time, the magnetic force of the magnetic structure 230 can be greater than that of the magnetic layer 150M, but is not limited thereto.

For example, the magnetic structure 230 can include a neodymium magnet, and the magnetic layer 150M of the semiconductor light emitting device can include any one of nickel, cobalt, and iron.

Next, referring to FIGS. 11C and 11D, when power is applied to the first and second assembly electrodes 210 and 220, the light emitting device 150N can be assembled into the assembly hole 220H by dielectrophoretic force (DEP) caused by an electric field. After assembly, as shown in FIG. 11D, the assembly device 1100 can be moved from the assembled area to another area.

Next, referring to FIG. 11E, even if the power is cut off to the first and second assembly electrodes 210 and 220, the dielectrophoretic force (DEP) due to the electric field disappears, the semiconductor light emitting device 150N cannot be separated from the assembly position by the third magnetic force MF3 between the magnetic structure 230 and the semiconductor light emitting device 150N.

For example, the magnetic structure 230 can be a ferromagnetic material stronger than the magnetic layer 150M, but is not limited thereto.

For example, the magnetic structure 230 can include a neodymium magnet, and the magnetic layer 150M of the semiconductor light emitting device can include any one of nickel, cobalt, and iron.

According to the embodiment, as shown in FIG. 11E, after the semiconductor light emitting device 150N is assembled in the assembly hole 220H using DEP force, by the third magnetic force MF3, which is an attractive force generated between the magnetic structure 230 disposed on the assembly substrate 200 and the magnetic layer 150M of the semiconductor light emitting device 150N in a situation where the DEP force is removed, as the semiconductor light emitting device 150N is fixed at the assembly position, there is a special technical effect that a highly reliable wiring process can be performed without using a separate fixing material in a subsequent wiring process.

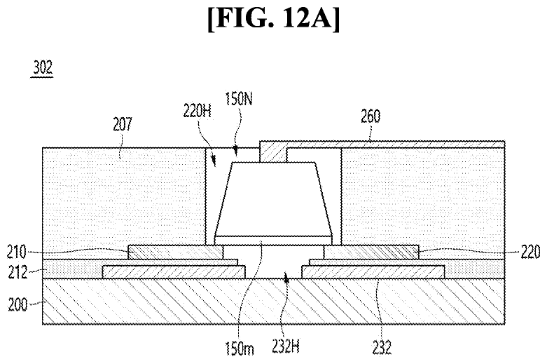

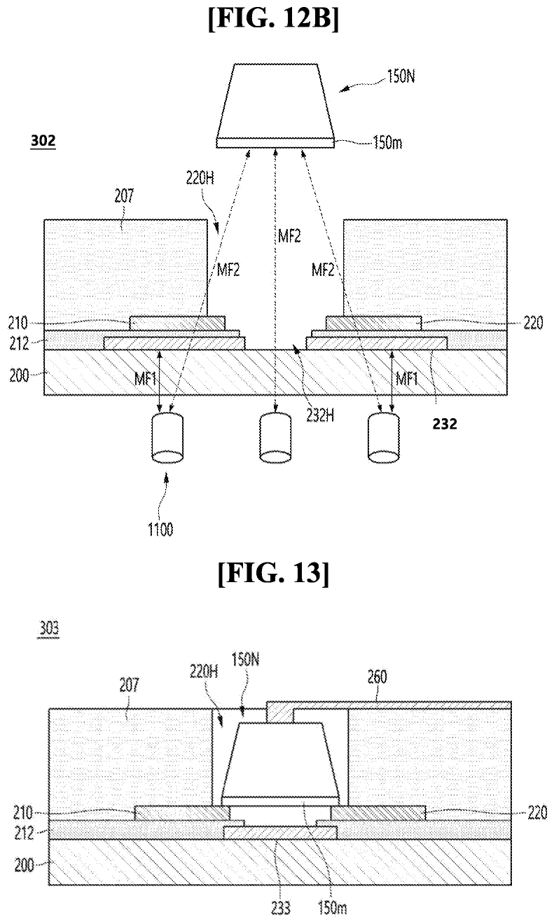

Next, FIG. 12A is a cross-sectional view of a display device 302 including a semiconductor light emitting device according to a second embodiment, and FIG. 12B is an exemplary view illustrating assembly features of a display device 302 having a semiconductor light emitting device according to a second embodiment.

The display device 302 including the semiconductor light emitting device according to the second embodiment can adopt the technical features of the display device 301 including the semiconductor light emitting device according to the first embodiment described above, hereinafter, the main features of the second embodiment will be mainly described.

Display device 302 having a semiconductor light emitting device according to the second embodiment can include a substrate 200, a first assembly electrode 210 and a second assembly electrode 220 disposed on the substrate 200, a second magnetic structure 232 disposed under the first assembly electrode 210 and the second assembly electrode 220, an insulating layer 212 disposed between the first and second assembly electrodes 210 and 220 and the second magnetic structure 232, a predetermined assembly hole 220H, an assembly barrier wall 207 disposed on the first and second assembly electrodes 210 and 220 and the semiconductor light emitting device 150N disposed in the assembly hole 220H.

The semiconductor light emitting device 150N can include a predetermined magnetic layer 150M.

The magnetic force of the second magnetic structure 232 can be greater than that of the magnetic layer 150M.

In the second embodiment, the second magnetic structure 232 can include a magnetic through hole 232H.

The magnetic material through-hole 232H can be disposed in an area overlapping the semiconductor light emitting device 150N vertically.

Referring to FIG. 12B, as the second magnetic structure 232 includes the magnetic through hole 232H in the second embodiment, the second magnetic force MF2 of the assembly device 1100 can be applied to the semiconductor light emitting device 150N through the magnetic through hole 232H. Accordingly, there is a special technical effect that can further improve assembly efficiency.

Next, FIG. 13 is a cross-sectional view of a display device 303 including a semiconductor light emitting device according to a third embodiment.

The display device 303 including the semiconductor light emitting device according to the third embodiment can employ the technical features of the first embodiment described above, and the main features of the third embodiment will be mainly described below.

Display device 302 having a semiconductor light emitting device according to the third embodiment can include a substrate 200, a first assembly electrode 210 and a second assembly electrode 220 disposed on the substrate 200, a third magnetic structure 233 disposed under the first assembly electrode 210 and the second assembly electrode 220, an insulating layer 212 disposed between the first and second assembly electrodes 210 and 220 and the second magnetic structure 232, a predetermined assembly hole 220H, an assembly barrier wall 207 disposed on the first and second assembly electrodes 210 and 220 and the semiconductor light emitting device 150N disposed in the assembly hole 220H.

The semiconductor light emitting device 150N can include a predetermined magnetic layer 150M.

The magnetic force of the third magnetic structure 233 can be greater than that of the magnetic layer 150M.

In the third embodiment, the horizontal width of the third magnetic structure 233 can be less than or equal to the horizontal width of the semiconductor light emitting device 150N.

The third magnetic structure 233 can be disposed between the first and second assembly electrodes 210 and 220 at a separation distance or less.

As the third embodiment includes the third magnetic structure 233 so that the semiconductor light emitting device can be fixed in the assembly position by magnetic force, which is an attractive force generated between the magnetic layers of the semiconductor light emitting device, there is a technical effect that a highly reliable wiring process can be performed without using a separate fixing material in the subsequent wiring process.

Also in the third embodiment, as the third magnetic structure 233 is disposed in an area overlapping the semiconductor light emitting device 150N vertically, there is a technical effect of maintaining the assembly position of the semiconductor light emitting device at the center of the assembly hole.

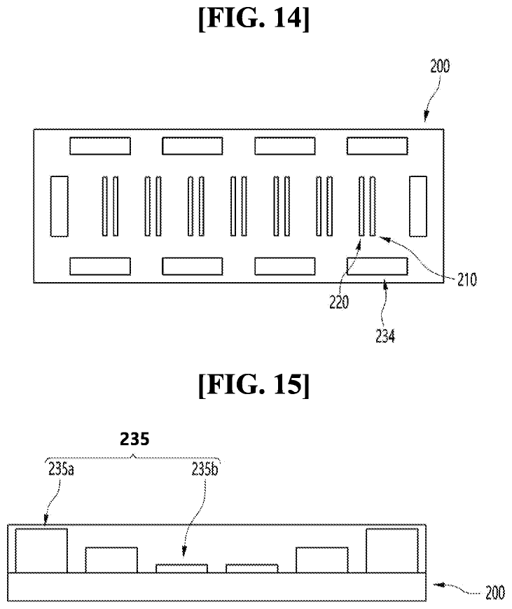

Next, FIG. 14 is a plan view of the assembly substrate 200 and the fourth magnetic structure 234 in the display device including the semiconductor light emitting device according to the fourth embodiment.

The fourth embodiment can employ the technical features of the first to third embodiments described above.

For example, the fourth embodiment can include at least one of the magnetic structure 230, the second magnetic structure 232, and the third magnetic structure 233 disposed under the first assembly electrode 210 and the second assembly electrode 220.

Meanwhile, in the fourth embodiment, the fourth magnetic structure 234 disposed around the outer circumference of the assembly substrate 200 on which the first and second assembly electrodes 210 and 220 are not disposed can be included.

According to the fourth embodiment, as the fourth magnetic structure 234 is disposed on the outer periphery of the assembly substrate 200, the distance between the substrate center and the edge portion of the substrate is more uniformly controlled by the magnetic force generated between the fourth magnetic structure and the assembling device 1100, which is a permanent magnet or an electromagnet, to prevent warpage, thereby improving the transfer rate.

Next, FIG. 15 is a cross-sectional view of the assembly substrate 200 and the fifth magnetic structure 235 in the display device including the semiconductor light emitting device according to the fifth embodiment.

The fifth embodiment can employ the technical features of the first to fourth embodiments described above.

For example, the fifth embodiment can include at least one of the magnetic structure 230, the second magnetic structure 232, and the third magnetic structure 233 disposed under the first assembly electrode 210 and the second assembly electrode 220.

Further, the fifth embodiment can include a fourth magnetic structure 234 disposed around the outer periphery of the assembly substrate 200.

Meanwhile, in the fifth magnetic structure 235 of the fifth embodiment, the thickness of the fifth-first magnetic structure 235a disposed on the outer portion of the assembly substrate 200 can be greater than the thickness of the fifth-second magnetic structure 235b disposed on the center portion of the assembly substrate 200.

According to the fifth embodiment, as the thickness of the fifth-first magnetic structure 235a disposed on the outer portion of the assembly substrate 200 is greater than the thickness of the fifth-second magnetic structure 235b disposed on the center portion of the assembly substrate 200, a greater magnetic force can be generated with the assembly device 1100.

According to the fifth embodiment, as the thickness of the fifth-first magnetic structure 235a disposed on the outer portion of the assembly substrate 200 is increased, there is a technical effect of improving the transfer rate by preventing warpage of the substrate, which is likely to occur at the edge of the substrate due to the greater magnetic force generated with the assembly device 1100.

The above detailed description should not be construed as limiting in all respects and should be considered as illustrative. The scope of the embodiments should be determined by reasonable interpretation of the appended claims, and all changes within the equivalent range of the embodiments are included in the scope of the embodiments.

The embodiment can be adopted in the display field for displaying images or information.

The embodiment can be adopted in the display field for displaying images or information using a semiconductor light emitting device.

The embodiment can be adopted in the display field for displaying images or information using micro-level or nano-level semiconductor light emitting devices.

What is claimed is:

1. An assembly substrate structure of a display device including a semiconductor light emitting device, the assembly substrate structure comprising:
an assembly substrate;
a first assembly electrode and a second assembly electrode spaced apart from each other on the assembly substrate;
a magnetic structure disposed below the first assembly electrode and the second assembly electrode; and
an insulating layer disposed between the first and second assembly electrodes and the magnetic structure.

2. The assembly substrate structure according to claim 1, wherein the magnetic structure comprises a magnetic through hole.

3. The assembly substrate structure according to claim 2, wherein the magnetic through hole vertically overlaps a separation space between the first assembly electrode and the second assembly electrode.

4. The assembly substrate structure according to claim 2, wherein the magnetic through hole exposes a surface of the assembly substrate.

5. The assembly substrate structure according to claim 1, wherein a horizontal width of the magnetic structure is less than or equal to a separation distance between the first assembly electrode and the second assembly electrode.

6. The assembly substrate structure according to claim 1, further comprising an outer magnetic structure disposed around an outer circumference of the assembly substrate.

7. The assembly substrate structure according to claim 1, further comprising an assembly barrier wall comprising an assembly hole and disposed on the first and second assembly electrodes.

8. The assembly substrate structure according to claim 1, wherein the insulating layer exposes a portion of the magnetic structure.

9. A display device comprising:
the assembly substrate structure according to claim 1; and
a plurality of semiconductor light emitting devices including the semiconductor light emitting device,
wherein the semiconductor light emitting device among the plurality of semiconductor light emitting devices has a magnetic layer and is disposed on the first and second assembly electrodes.

10. The display device according to claim 9, wherein a magnetic force of the magnetic structure is greater than a magnetic force of the magnetic layer.

11. The display device according to claim 9, wherein a thickness of the magnetic structure is greater than a thickness of the magnetic layer.

12. The display device according to claim 9, wherein a magnetic through hole is disposed in an area of the magnetic structure overlapping the semiconductor light emitting element.

13. The display device according to claim 9, wherein a horizontal width of the magnetic structure is less than or equal to a horizontal width of the semiconductor light emitting device.

14. The display device according to claim 9, wherein in the magnetic structure, a thickness of a fifth-first magnetic structure disposed on an outer portion of the assembly substrate is greater than that of a fifth-second magnetic structure disposed on a center portion of the assembly substrate.

15. The display device according to claim 9, wherein a portion of an upper surface of the magnetic structure is covered by the insulating layer.

16. The display device according to claim 9, wherein all side surfaces of the magnetic structure are in contact with the insulating layer.

17. The display device according to claim 9, wherein a horizontal width of a magnetic through hole is less than or equal to a separation distance between the first assembly electrode and the second assembly electrode.

18. An assembly substrate structure of a display device including a semiconductor light emitting device, the assembly substrate structure comprising:
an assembly substrate;
a first assembly electrode and a second assembly electrode spaced apart from each other on the assembly substrate;
a plurality of magnetic structures on the assembly substrate, and
an insulating layer on the assembly substrate and overlapping the first and second assembly electrodes and the plurality of magnetic structures.

19. The assembly substrate structure according to claim 18, wherein the plurality of magnetic structures include:
a first magnetic structure between the assembly substrate and the first and second assembly electrodes, and extending between the first assembly electrode and the second assembly electrode; or
a second magnetic structure between the assembly substrate and the first and second assembly electrodes, and including a magnetic through hole; or
a third magnetic structure between the assembly substrate and the first and second assembly electrodes, and having a width that is less than or equal to that of an assembly hole of the assembly substrate structure.

20. The assembly substrate structure according to claim 19, wherein the plurality of magnetic structures further includes at least one of:
a fourth magnetic structure disposed around an outer circumference of the assembly substrate; and
a fifth magnetic structure having discrete parts and located between the assembly substrate and the first and second assembly electrodes.
